(19) United States
(12) Patent Application Publication
(10) Pub. No.: US 2024/0160982 A1
(43) Pub. Date: May 16, 2024

(54) QUANTUM DEVICE

(71) Applicant: NEC Corporation, Tokyo (JP)

(72) Inventors: Katsumi KIKUCHI, Tokyo (JP); Akira Miyata, Tokyo (JP)

(73) Assignee: NEC Corporation, Tokyo (JP)

(21) Appl. No.: 18/388,563

(22) Filed: Nov. 10, 2023

(30) Foreign Application Priority Data
Nov. 16, 2022 (JP) 2022-183516

(51) Int. Cl. G06N 10/20

(52) U.S. Cl. CPC G06N 10/20

(57) ABSTRACT

A quantum device includes a first chip and a second chip that are assembled to configure a three-dimensional wiring structure. The first chip includes a protruding region protruded from a side edge of an outer periphery of the second chip and includes terminals on the protruding region.

### CROSS REFERENCE TO RELATED APPLICATIONS

This application is based upon and claims the benefit of the priority of Japanese patent application No. 2022-183516, filed on Nov. 16, 2022, the disclosure of which is incorporated herein in its entirety by reference thereto.

### FIELD

This disclosure relates to a quantum device. In particular, the present disclosure relates to a quantum device including superconducting quantum circuit.

### BACKGROUND

In a quantum device including a superconducting quantum bit (qubit) circuit, technology studies are underway to implement a device with three-dimensional architecture in place of two-dimensional architecture in accordance with an increase in the number of qubits included in the circuit. As a related technology for a quantum device with three-dimensional wiring structure, for example, Patent Literature (PTL) 1 discloses a quantum device of a stacked structure that includes a first chip 202 and a second chip 204 facing to the first chip 202 by bump bonding 214. The first chip 202 includes an array of qubit circuits 206. The second chip 204 includes readout devices 208 for the qubit circuits 206 and control elements 210 and 212, as illustrated in FIG. 8.

PTL 2 discloses a configuration in which first and second quantum bit substrates are face-down mounted on a base substrate. Two end portions of a first superconductive wire of the first quantum bit substrate and two end portions on one side of a third superconductive wiring on the base substrate are joined via superconductive solders. Two ends of a second superconductive wire of the second quantum bit substrate and two end on the other side of the third superconductive wire are joined via superconductive solders. Thus, the first to third superconductive wirings form a single continuous superconductive loop. PTL 3 discloses a quantum computing apparatus including a quantum circuit device and an interposer with the quantum circuit device attached thereto, wherein the interposer includes an intermediate layer that connects to a terminal (electrical contact) on a surface of the quantum circuit device, and a connectorization layer that supports the intermediate layer and has a connector for cable. Further, PTL 4 discloses a configuration including a first chip including a qubit(s) and a second chip bonded to the first chip, wherein the second chip includes a substrate having first and second opposing surfaces and the first surface faces the first chip.
PTL 1: U.S. Unexamined Patent Application Publication No. 2020/0058702 A1
PTL 2 International Publication No. WO2018/212041
PTL 3: U.S. Pat. No. 9,836,699 B2
PTL 4: Japanese Patent No. 6789385

### SUMMARY

The quantum device of a stacked structure described as the above related technology is configured with multiple components (e.g., multiple chips). Testing of an individual one of the multiple components before assembling of the multiple components alone cannot ensure or determine characteristics of a qubit circuit of the quantum device composed by assembling of the multiple components.

It is an object of the present disclosure to provide a quantum device enabling testing thereof with stable connection performance and allowing to secure a terminal region(s) for external connection, wherein the quantum device includes a plurality of chips configuring a superconducting quantum circuit of a three-dimensional wiring structure.

According to one aspect of the present disclosure, there is provided a quantum device including a first chip and a second chip. The first chip and the second chip are assembled to configure a superconducting quantum circuit of a three-dimensional wiring structure. The first chip includes a protruding region protruded from a side edge of an outer periphery of the second chip and at least one terminal disposed on the protruding region.

According to the present disclosure, it is possible to provide a quantum device that includes a plurality of chips configuring a superconducting quantum circuit of a three-dimensional wiring structure, enables testing thereof with stable connection performance and allows to secure a terminal region(s) for external connection.

### BRIEF DESCRIPTION OF DRAWINGS

FIG. 1A is a schematic perspective view illustrating a configuration of the present disclosure.

FIG. 1B is a schematic plan view illustrating a configuration of the present disclosure.

FIG. 1C is a schematic end view illustrating a configuration of the present disclosure.

FIG. 2A is a schematic plan view illustrating the present disclosure.

FIG. 2B is a schematic plan view illustrating the present disclosure.

FIG. 3A is a schematic plan view illustrating a non-limiting example of a second quantum chip of the present disclosure.

FIG. 3B is a schematic plan view illustrating a non-limiting example of a first quantum chip of the present disclosure.

FIG. 3C is a schematic cross-sectional view illustrating a non-limiting example of a quantum device of the present disclosure.

FIG. 3D is a schematic cross-sectional view illustrating a quantum device of the present disclosure.

FIG. 4 is a schematic plan view illustrating a non-limiting example of the quantum device of the present disclosure.

FIG. 5A is a schematic plan view illustrating a non-limiting example of a circuit under test (qubit) of the present disclosure.

FIG. 5B is a schematic plan view illustrating a non-limiting example of a circuit under test (qubit) of the present disclosure.

FIG. 5C is a schematic plan view illustrating a non-limiting example of a circuit under test (coupler) of the present disclosure.

FIG. 6 is a schematic plan view illustrating a probe test of the present disclosure.

FIG. 7 is a schematic plan view illustrating variations of the present disclosure.

FIG. 8 is a diagram illustrating a related art (PTL 1).

### EXAMPLE EMBODIMENTS

Testing of a device with a probe (termed also as a probe pin, or a probe needle) contacting to a pad (connection terminal) of the device is, in some cases, accompanied by irregularities (scratches or contact marks) on a surface of the pad. The same may be said to testing of a quantum device composed by assembling multiple chips, with a tip of a probe (e.g., high-frequency probe) contacting to a pad of the device. The quantum device, which has passed the testing using the probe, is connected to a substrate (PCB (Printed Circuit Board)) or the like) which includes a connector connected, by a coaxial cable or the like, to a signal generator and/or a signal receiver (readout portion) externally provided. The quantum device which has undergone the probe test, in operation, may have difficulty in securing a stable connection between the pad of the quantum device and a pad of the substrate (PCB), for example.

To address this problem, such a configuration may be conceived in which a pad(s) dedicated for testing (not used for actual operation) of a qubit circuit is/(are) disposed on the quantum device composed by assembling multiple components. However, this configuration would deprive a region with a connection terminal(s) for external connection disposed thereon. For example, when a second chip, which is mounted on a first chip, includes a connection terminal(s) for external connection and a pad(s) dedicated for testing, on a second surface of the second chip, opposite to a facing surface (a first surface) that faces the first chip, a region on which the connection terminal(s) for external connection is/(are) disposed is limited by the region provided for the pad(s) dedicated for testing.

The issue described above is just one example. The present disclosure makes it possible in various situations to improve a connection performance in testing of a quantum device including multiple chips configured to implement a superconducting quantum circuit(s) of a three-dimensional wiring structure, and/or to secure a region of a connection terminal for external connection in the quantum device. The following describes several examples. In the following description of examples, reference is made to the accompanying drawings in which, by way of illustration, specific examples that can be practiced are shown. It is to be understood that other examples can be used and structural changes can be made without departing from the scope of the various examples. It is noted that in the disclosure, the expression “at least one of A and B” means A, B, or (A and B). The term expressed as “-(s)” includes both singular and/or plural form.

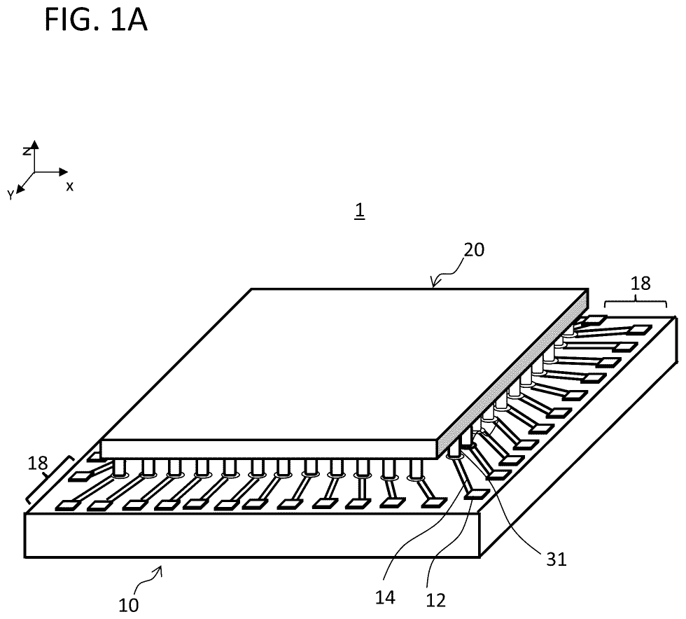

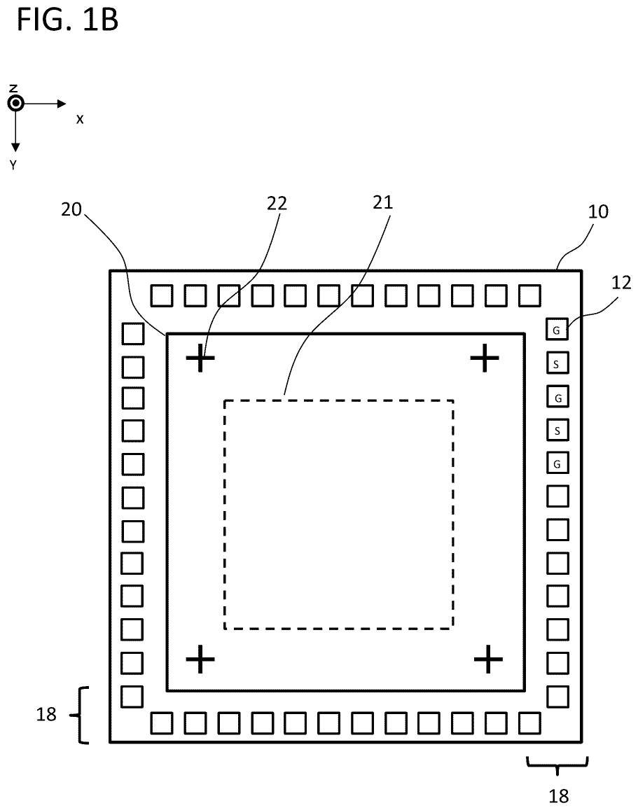

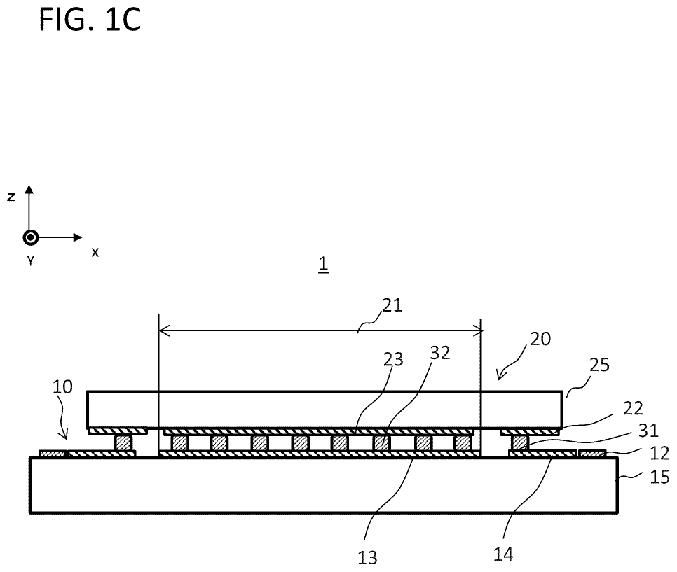

FIG. 1A is a schematic perspective view illustrating a configuration of an example of the disclosure. Referring to FIG. 1A, a quantum device 1 includes a first chip 10 and a second chip 20 stacked on the first chip 10. The second chip 20 is face-down mounted on a first surface (front surface) of the first chip 10, in which a first surface of the second chip 20 is faced to the first surface of the first chip 10. On the first surface of the second chip 20, a superconducting quantum circuit, such as qubit(s) (quantum bit(s)) and a coupler, is formed. As for each of the first chip 10 and the second chip 20 placed opposite to each other, a facing surface will be referred to a first surface. As illustrated in FIG. 1A, a planar shape (rectangular) of the first chip 10 is larger than that of the second chip 20. The first chip 10 includes a region (protruding region) 18 protruded outward from a side edge of an outer periphery of the second chip 20 mounted on the first surface of the first chip 10. Multiple terminals (electrode pads) 12 dedicated for testing are disposed on the protruding region 18 of the first chip 10 along the side edge of the first chip 10.

FIG. 1B is a schematic plan view of the quantum device 1 illustrated in FIG. 1A seen from above (a positive direction of the z-axis). In FIG. 1B, a region 21 surrounded by a broken line on the second chip 20 is a region in which a superconducting quantum circuit is arranged. A cross-shape designated by a reference numeral 22 indicates a circuit to be tested (circuit under test: CUT). The circuit under test 22 is disposed on the second chip 20 in a region of different from the region 21 in which the quantum circuit is are provided. The circuit under test 22 may be a qubit circuit that has a configuration same as that of the qubit circuit disposed in the region 21 of the second chip 20.

The circuit under test 22 is preferably disposed at an outer periphery portion of the second chip 20 on a wiring layer of the first surface (front surface) of the second chip 20, in consideration of a connection distance with a terminal (pad) 12 dedicated for testing which is provided at an outer periphery of the first chip 10. The circuit under test 22 is preferably disposed at least one corner of four corners of the second chip 20 in view of a position accuracy in mounting of the second chip 20 on the first chip 10. In FIG. 1A and FIG. 1B, rows of terminals (pads) 12 dedicated for testing are provided at a prescribed pitch along the entire range of each of four sides in the outer periphery portion on the first surface (front surface) of the first chip 10. In the example of FIG. 1B, there is no region in each side of the first chip 10 that lacks the terminal 12 or a row of the terminals 12. It is noted that the outer periphery portion of the first the first chip 10 may have a region in a side that lacks the terminal 12 or a row of the terminals 12, i.e., the terminals 12 are provided in a partial range of the side.

FIG. 1C is a schematic end view of the quantum device 1 illustrated in FIG. 1A seen from a side surface (a positive direction of the y-axis). In FIG. 1C, wiring layers, bumps, and pads are illustrated with a hatching to represent a cross section of a metal component. The first chip 10 has a wiring layer 13 formed on a first surface (a surface facing the first surface of the second chip 20) of a substrate 15. A connection terminal (wiring pad) of a qubit circuit, which is disposed in the region 21 of a wiring layer 23 on the first surface of a substrate 25 of the second chip 20, is connected electrically to a connection terminal (wiring pad) of the wiring layer 13 on the first surface of the first chip 10, via a bump (metal protrusions) 32. A connection terminal of the circuit under test 22 disposed outside of the region 21 of the wiring layer 23 on the first surface of the second chip 20, is connected via h a bump (metal protrusion) 31 to a wiring pad on the first surface of the first chip 10, which is connected by a wiring 14 to the terminal 12. The qubit circuit disposed in the region 21 of the wiring layer 23 of the second chip 20 and the circuit under test 22 may be formed using a lithographic patterning process of a semiconductor process to fabricate the second chip 20. The wiring layer 13, the wiring 14 and the terminals 12 of the first chip 10 may be formed by a lithographic patterning process in a semiconductor process to fabricate the first chip 10.

The circuit under test 22 may be a resonator including a Josephson junction which is a nonlinear element, an oscillator such as a Josephson Parametric Oscillator, a coupler including a Josephson junction, a Superconducting Quantum Interference Device (SQUID) including two or more Josephson junctions in a loop, a magnetic-field application circuit, and/or a qubit. The circuit under test 22 may be a LC resonator (made of a superconducting material) without a Josephson junction.

In an example illustrated in FIG. 1A, the wiring layer 23 and the circuit under test 22 on the first surface of the second chip 20 are connected via bumps 32 and 31 to the wiring pads on the first surface of the first chip 10, respectively. However, the wiring layer 23 and the circuit under test 22 may be respectively connected to the wiring pads by wireless coupling (a capacitive coupling or an inductive coupling).

Referring to FIG. 1B, as terminals 12 disposed on the outer periphery portion of the first chip 10, a ground terminal (G) is disposed between signal terminals (S) that receive and/or output signals to the circuit under test 22. A length of the ground terminal (G) along a side of the first chip 10 may be equal to or greater than that of the signal terminal (S). Alternatively, multiple ground terminals (G) may be disposed between adjacent signal terminals (S). The ground terminal(s) (G) (ground pattern) may be disposed between the signal terminals (S) to reduce crosstalk noise. The ground terminal (G) of the terminal 12 on the outer periphery of the first chip 10 may be connected via the wiring 14 and via one or more bumps 31 to a ground plane (ground pattern) of the wiring layer 23 of the second chip 20. Alternatively, a ground plane of the wiring layer 13 of the first chip 10 may be extended or connected to the ground terminal (G) of the terminal 12.

In the second chip 20, the circuit under test 22 is preferably disposed at an outer periphery portion of the second chip 20. One reason is that, since the circuit under test 22 of the second chip 20 is to be connected to the terminal 12 disposed at an outer edge of the first chip 10, a wiring length becomes shorter when the circuit under test 22 is disposed at an outer edge region of the second chip 20 than when the circuit under test 22 is disposed inside the region 21 (a region where a qubit circuit is disposed) of the second chip 20. Another reason is that when the circuit(s) under test 22 is(are) disposed inside the region 21 of the second chip 20, a total area for the qubit circuit in the region 21 of the second chip 20 is reduced by an area for the circuit (s) under test 22.

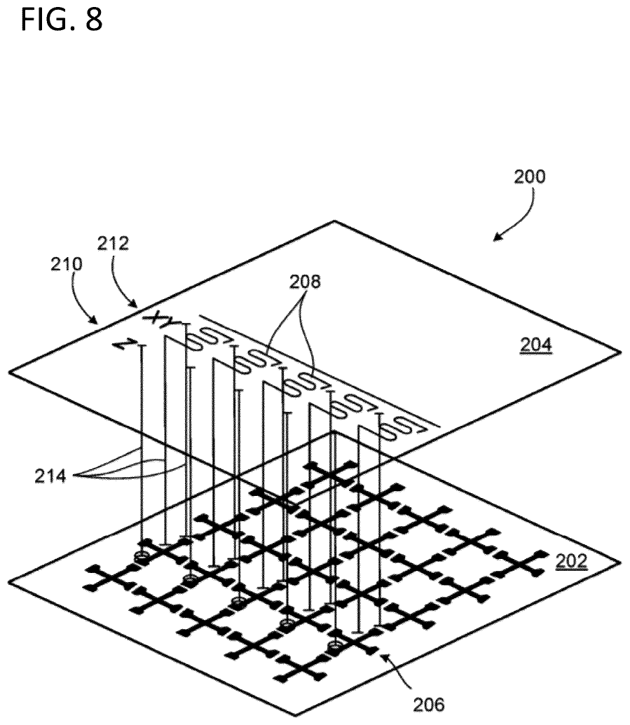

Further, the circuit(s) under test 22, when disposed inside the region 21 of the second chip 20, may have an effect on the qubit circuit, when the quantum device 1 is actually used after testing of the quantum device 1. This is also the reason for disposition of the circuit under test 22 at an outer edge region of the second chip 20. For example, in FIG. 8, when estimating characteristics of a qubit circuit 206, a readout element dedicated for testing of the qubit circuit 206 needs to be provided in the second chip 204 separately from a normal readout element 208 of the qubit circuit 206 and to be connected to a port(s) dedicated for testing of the qubit circuit 206 of the first chip 202 via bump, etc. In this case, the port(s) dedicated for testing of the qubit circuit 206 is/(are) left, even after testing, in close proximity to the qubit circuit 206, in addition to a port(s) for normal operation (readout port). Input/output signal to/from the qubit circuit 206 in normal operation may also be coupled (e.g., capacitively coupled or inductively coupled) to the port(s) dedicated for testing to cause leakage and/or reflection of the signal, which affects a performance of the qubit circuit 206.

In the second chip 20, the circuit under test(s) 22 is preferably disposed at one of four corners of the second chip 20, three corners thereof, two corners thereof, or one corner thereof. This is because the corner(s) of the second chip 20 is(are) greatly affected by pattern misalignment, etc., depending on mounting accuracy of the chip.

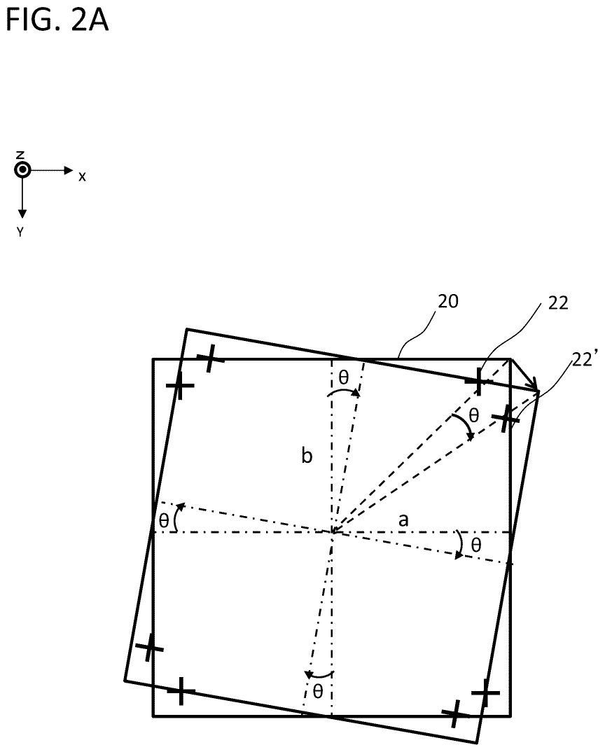

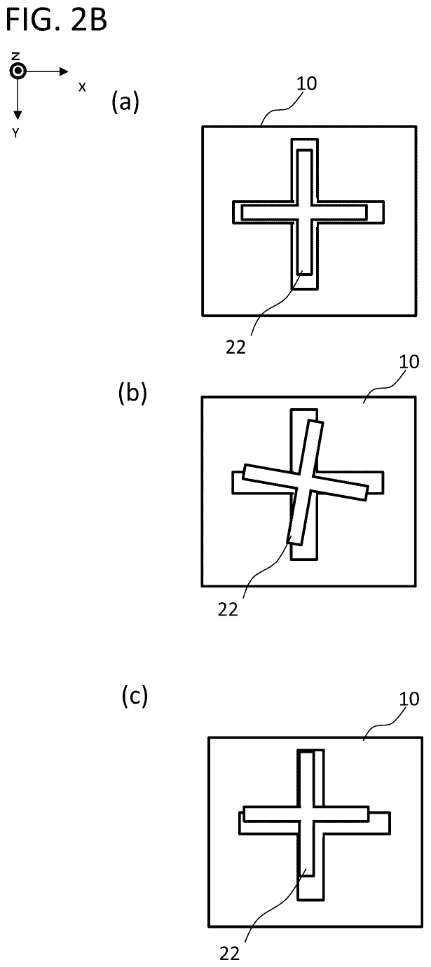

For example, as schematically illustrated in FIG. 2A, assume that a planar shape of the second chip 20 is a rectangular shape with height 2a and width 2b (b<a), and there is a misalignment of angle θ at the center, the circuit under test 22 moves to the position 22′. The corner of the second chip 20 is displaced approximately (\sqrt{a²+b²}) sin θ=(\sqrt{a²+b²})·θ in the direction of arrows in the drawing, resulting in a sin θ displacement at a midpoint of a vertical side, b sin θ displacement at a midpoint of a lateral side, resulting in a smaller displacement than (\sqrt{a²+b²})sin θ between the midpoint of the side and one end of the side. Therefore, due to disposition of the circuit under test 22 at corner portion(s) of the second chip 20, a separation distance between the circuit under test 22′, which has an angle θ misalignment, and the circuit under test 22 in its original position is larger than when the circuit under test 22 is disposed in other positions.

In the second chip 20, the circuit(s) under test 22 is(are) not to be disposed only at the corner of the second chip 20, but, of course, one to four circuit(s) under test 22 can be disposed in the corner(s) of the second chip 20 and other circuit under test 22 can be disposed along a side between the corners.

FIG. 2B schematically illustrates examples of displacement of a circuit (wiring) pattern of the second chip 20 mounted on the first chip 10. In an example (a) of FIG. 2B, the circuit under test 22 of the second chip 20 is mounted properly with respect to the first chip 10. In an example (b) of FIG. 2B, there is a rotational misalignment in a mounting position of the circuit under test 22 of the second chip 20 with respect to the first chip 10. In an example (c) of FIG. 2B, there is a misalignment in the x-y coordinate plane in a mounting position of the circuit under test 22 of the second chip 20 with respect to the first chip 10.

The larger a pattern misalignment between the first chip 10 and the second chip 20, the closer a ground (GND) pattern is to each circuit, resulting in a larger capacitance between the circuit and the GND. When a coupling force between a circuit (e.g., a resonator, an oscillator, or a coupler) and the GND (capacitive coupling by a capacitance between the circuit and the GND) changes, a coherence state which indicates a quantum property changes. For example, the stronger a coupling, the greater an energy loss, resulting in a shorter a coherence time (a length of time a quantum superposition state survives). Measurement of a critical current value Ic of a Josephson junction in a SQUID included in the circuit under test 22 may be performed and checked whether the critical current Ic maintains a predetermined current value range to determine the performance (characteristics) of the circuit under test 22. When the circuit under test 22 is a qubit circuit, a coupler or the like, Q-value, etc., may be measured.

In FIG. 1C, the substrate 25 of the second chip 20 includes, for example, silicon (Si). It is noted that the substrate 15 is not limited to those including silicon and may include those including other electronic materials, such as sapphire or a compound semiconductor material (elements of Groups IV, III-V, and II-VI). Further, the material is preferably a single-crystalline material, but it may be a polycrystalline material or an amorphous material.

The wiring layer 23 on the first surface of the second chip 20 includes a wiring pattern(s) of a superconducting quantum circuit and a ground plane (ground pattern). The wiring layer 23 (including wiring of the circuit under test 22) includes a superconducting material such as niobium (Nb). The superconducting material used in the wiring layer 13 is not limited to niobium (Nb). For example, the superconducting material may include niobium nitride, aluminum (Al), indium (In), lead (Pb), tin (Sn), rhenium (Re), palladium (Pd), titanium (Ti), or an alloy including at least one selected therefrom.

The wiring layer 23 and the circuit under test 22 on the first surface of the second chip 20 are faced to the wiring layer 13 on the first surface of the first chip 10 and connected thereto via bumps 32 and 31. Terminals (wiring pads) of the wiring layer 23 and the circuit under test 22 on the first surface of the second chip 20 are directly connected to the corresponding terminals (wiring pads) of the wiring layer 13 and the wiring pads of the wiring 14 on the first surface of the first chip 10, respectively. The bumps 32 and 31 may be formed on the wiring layer 13 on the first surface of the first chip 10, or on the wiring layer 23 side on the first surface of the second chip 20.

The bump(s) 31 may have a protrusive shape suitable for controlling a height of a spacing between substrates to be bonded. More specifically, the bump(s) 31 may have a three-dimensional shape selected from any ones such as a columnar (cylindrical, polygonal, etc.), conical (can include conical, pyramidal, as well as truncated cone, truncated pyramid, etc.), spherical, or rectangular shape. The bump(s) 31 (32) may be configured by a normal-conducting material and formed by laminating a superconducting material(s). The bump(s) 31 may include the same superconducting material as the wiring layer 23 of the second quantum chip 20 or may include a different superconducting material than the wiring layer 23.

As for the bump 31 with multiple metal layers, it is preferable that at least one layer of the bump 31 includes a superconducting material. The bump(s) 31 (32) may have a layered structure including Nb/In (Sn, Pb, or an alloy including at least one of Sn or Pb) /Ti/Nb (a surface of the wiring layer 13 of the first chip 10) /Cu, a layered structure including Nb (a surface of the wiring layer 23 of the second chip 20) Nb (a surface of the wiring layer 13 of the first chip 20) /Cu, or a layered structure including /Nb (the surface of the wiring layer 23 on the second chip 20) /In (Sn, Pb, or an alloy including at least one of Sn or Pb) /Ta (a surface of the wiring layer 13 of the first chip 10) /Cu. Further, in case where the bump(s) 31 (32) includes Al and In, TiN may be used for a barrier layer to prevent alloying of Al and In. In such a case, the bump(s) 31(32) may have a layered structure including Al (the surface of the wiring layer 23 of the second chip 20) /Ti/TiN/In (Sn, Pb, or an alloy including at least one of Sn or Pb) /TiN/Ti/Al (the surface of the wiring layer 13 of the first chip 10) /Cu, where Ti is an adhesion layer. A flip-chip connection is preferably implemented by Nb (the surface of the wiring layer 23 of the second chip 20) /In/Ti/Nb (the surface of the wiring layer 13 of the first chip 10) /Cu, or Nb (the surface of the wiring layer 23 the second chip 20) /Nb (the surface of the wiring layer 13 of the first chip 10) /Cu. Alternatively, the bump(s) 31 (32) is made of a normal conducting material such as Cu or silicon dioxide (SiO₂), and may have a surface thereof covered with a film of a superconducting material.

As a non-limiting example, a width of the bump(s) 31(32) may be on an order of a few or several to a few or several tens of micrometers, and a height of the bump(s) 31(32) may be on an order of a few or several to a few or several tens of micrometers. The first chip 10 and the bump(s) 31(32) may be bonded using such as solid phase bonding. A refrigerator is subjected to vacuum-evacuation. Regarding solid-phase bonding methods, surface activation bonding SAB or ultrasonic bonding may be used. Alternatively, melt joining may be used in a case where high temperature can be applied during bonding. Pressure welding may be used in a case where a resin can be used.

In a case where the substrate 25 of the second chip 20 is silicon, silicon may be used for the substrate 15 of the first chip 10 in consideration of a linear expansion coefficient, etc. In this case, the first chip 10 may be also referred to as a silicon interposer. The substrate 15 is not limited to one including silicon. The substrate 15 may include other electronic materials such as sapphire or compound semiconductor materials (group IV, III-V and II-VI), glass, and ceramics. The bumps 31 and 32 may be formed on the wiring layer 13 on the first surface during a fabrication process of the first chip 10.

The wiring layer 13 on the first surface of the first chip 10 includes the superconducting material mentioned above. The wiring layer 13 on the first surface may include the same superconducting material as that included in the wiring layer 23 on the first surface of the second chip 20, and/or a superconducting material different from that included therein.

It is possible to perform GO-NO-GO decision (screening) of the first chip 10 and the second chip 20, individually, on a basis of their circuit shapes, etc. However, the individual GO-NO-GO decision (screening) of the first chip 10 and the second chip 20 does not necessarily make it possible to determine characteristics (such as coherence time and/or related Q values) of the qubit circuit after assembling of the first chip 10 and the second chip 20 (after mounting of the second chip 20 on the first chip 10).

When a proximity distance between different circuits changes, such as the qubit circuit on the first surface of the first chip 10 and the qubit circuit on the first surface of the second chip 20, characteristics of the qubit circuits change. This is one of factors for a change in the characteristics of the qubit circuit after assembling of the first chip 10 and the second chip 20. In addition to the planar misalignment illustrated in FIG. 2B, a distance between facing surfaces of the first chip 10 and the second chip 2 also affects the characteristics of the qubit circuit of the quantum device.

Misalignment of the first chip 10 and the second chip 20 caused by bump connections, etc., is also a factor of changes in the characteristics of the qubit circuit after assembling of the first chip 10 and the second chip 20. It is preferable to suppress height variation at a connection portion between the first chip 10 and the second chip 20.

Not only suppressing height variation low at connection electrodes (bumps)/connection terminals (pads), but also it is preferable to keep a flatness of connection surfaces of the first chip 10 and the second chip 20 high. Dielectric, such as underfill to protect the connection portion, cannot be placed because the dielectric may cause degradation of the characteristics of the qubit circuit.

Therefore, a predetermined level of height variation and flatness is required to obtain connection stability between the first chip 10 and the second chip 20. For example,
height variation: between +15% and −15%, preferably between +10% and −10%, more preferably, between +5% and −5%;
flatness: an arithmetic mean roughness (Ra) of 1 nm (nanometer) or less, preferably 0.5 nm or less, more preferably 0.1 nm or less, and bonded with a superconducting material (but not limited to the above).

In the quantum device 1 composed by assembling of the first chip 10 and the second chip 20, similarly, dielectric, such as underfill to protect the connection portion, cannot be used also for the connection terminals (pads) for external connection. A predetermined level of height variation and flatness of a connection terminal surface is required. Thus, a test using a probe pin which may damage (scratch) the connection terminal surface (pad) for external connection cannot not conducted.

For the above reasons, in the present disclosure example, when testing the qubit circuit, the terminals (pads) which are not connected to connection electrodes, etc., are used as terminals dedicated for testing.

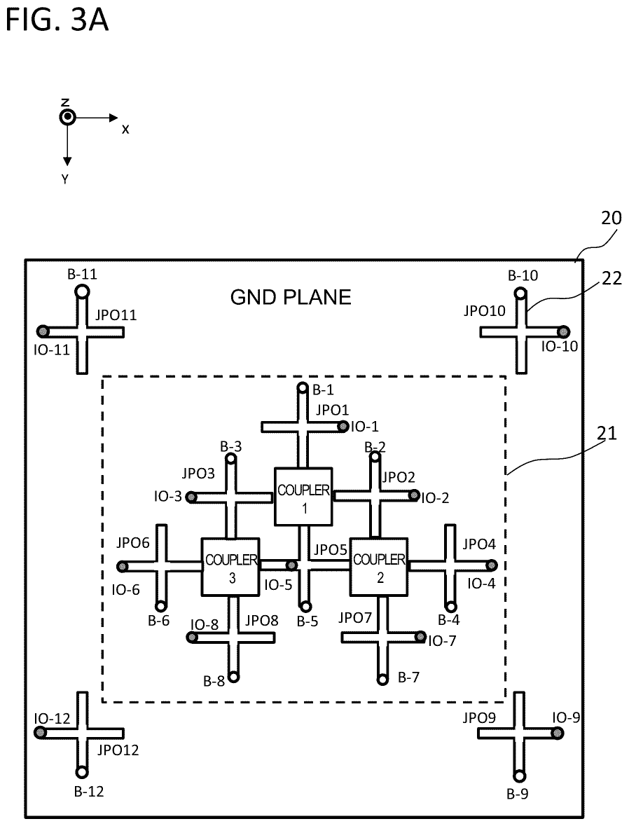

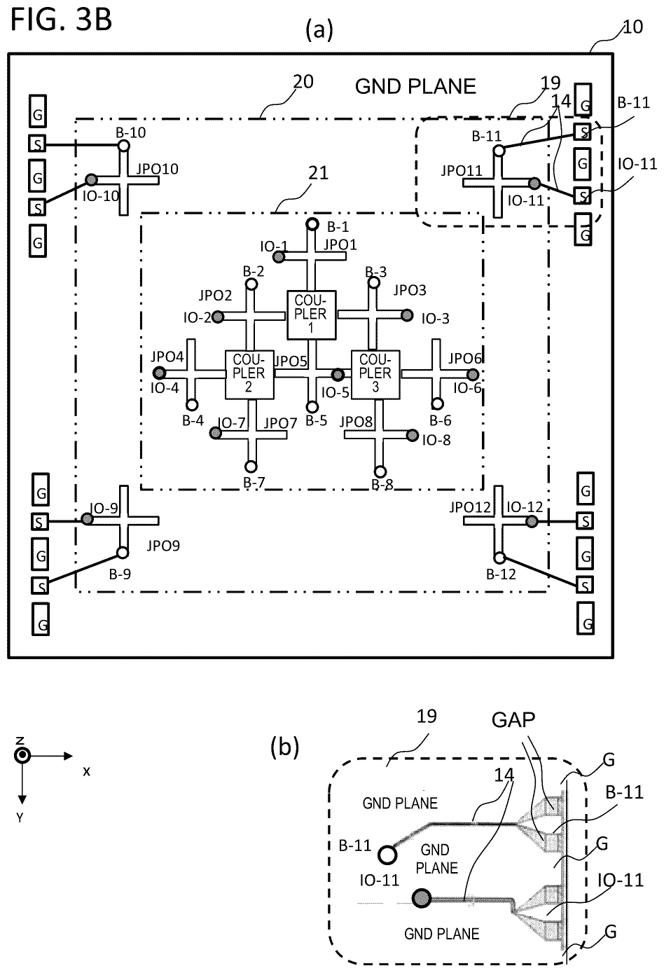

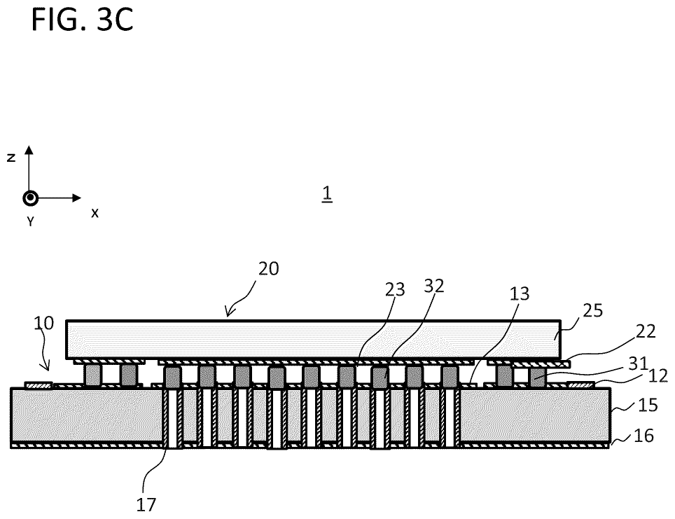

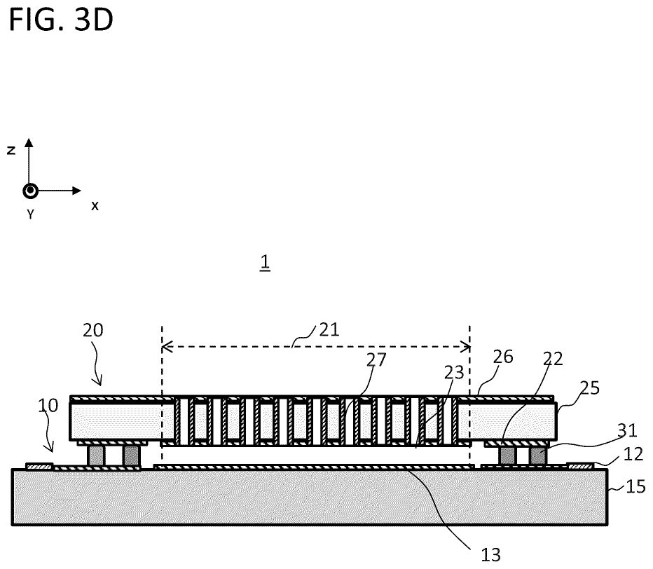

FIG. 3A is a schematic plan view illustrating a non-limiting example of a second chip 20. In a region 21 of the wiring layer 23 of the second chip 20, a wiring pattern of a quantum annealing machine using a Josephson parametric Oscillators (JPOs) with neighboring four-body interaction by LHZ (Lechner, Hauke, Zoller) scheme is fabricated. The LHZ scheme solves an optimization problem requiring control of long-range interactions between many Ising spins by mapping them onto a graph of local interactions, where pairs of N logical spins are mapped to M=N (N−1)/2 physical spins. In the region 21 illustrated in FIG. 3A, an all-to-all connected (fully connected) Ising machine with M=4 logical spins is schematically illustrated. A network is provided with three couplers (coupler 1, 2 and 3) and six qubits (JPO 1 to JPO 6). Qubits (JPO 7 and JPO 8) are fixed bits. Each qubit is configured by a Josephson Parametric oscillator (JPO). Multiple JPOs and multiple couplers are arranged in a pyramidal square lattice. The coupler and four neighboring qubits (JPOs) which are capacitively coupled to the coupler, configure a unit structure (basic unit, also termed plaquette). The JPOs each have an IO (input/output) line and a pump line. At each of four corners outside of the region 21 of the wiring layer 23 of the second chip 20, a qubit (JPO) with the same configuration as the qubit (JPO) being disposed within the region 21 and configuring the Ising machine is arranged, as a circuit under test 22. Each JPO is made of superconducting material and has, as a planar shape, for example, a cross-shaped electrode structure with arms of equal length and crossing each other at right angles at the center. A coupling port (IC) port) of the IO line that is capacitively coupled to one of the four arms of the cross-shape electrode of the JPO is illustrated as a white circle, and a coupling port (pump port) of the pump line that is inductively coupled to a SQUID resonator connected to one of the arms of the cross-shape electrode of the JPO is illustrated as a gray circle. In FIG. 3A, IO ports IO-9 to IO-12 and pump ports B-9 to B-12 are connected to a wiring layer of the first chip 10 via bumps (not shown). The planar shape of the JPO is, as a matter of course, not limited to the cross-shape.

FIG. 3B (a) is a plan view schematically illustrating one example of a case in which the first chip 10 and the second chip 20 are assembled with the first surface of the first chip 10 opposed and connected to the first surface of the second chip 20 via bumps (31 and 32). In FIG. 3B (a), in the wiring layer 13 of the first chip 10, wiring pads connected to the wiring pads provided in the region 21 of the wiring layer 23 of the second chip 20 by the bumps 32 and a wiring pattern in the region 21 (two-dot dash line) of the wiring layer 23 of the second chip 20 are illustrated superimposed. In FIG. 3B (a), IO-9 to IO-12 and B-9 to B-12 also represent pads on the wiring layer of the first chip 10 which are connected to IO ports IO-9 to IO-12 of JPO 9 to JPO 12 by the bumps 31, respectively. The JPO 9 to JPO 12 are circuits under test 22 disposed at four corners of the second chip 20, respectively. The pads B-9 to B-12 and IO-9 to IO-12 are connected to the terminals 12 (signal terminals) by signal wirings, respectively. Between the terminals (signal terminals (S)), to which the pads IO-11 and B-11 on the wiring layer of the first chip 10 connecting to the IO port IO-11 and the pump port B-11 of the JPO 11 on the wiring layer of the second chip 20, respectively, are connected, a double sized ground terminal (G) is disposed.

Pads IO-11 and B-11 and terminals IO-11 and B-11 in a region 19, corresponding to a corner portion of the second chip 20, of the wiring layer 13 of the first chip 10 are surrounded by a ground plane (ground pattern) with a gap around each edge. The wirings (signal wirings) 14 which connect pads IO-11 and B-11 and terminals (IO-11) and (B-11), respectively, are configured as a coplanar line in which the ground planes (ground pattern) are arranged on both of longitudinal sides of the line via gaps.

Regarding an array of terminals 12 in the outer periphery portion of the first chip 10, the signal terminals (S) are surrounded by the ground plane. As illustrated in FIG. 3B(b), the double sized ground terminal (G) disposed between adjacent signal terminals (S) (terminal (IO-11) and terminal (B-11)) serves as a ground plane (ground pattern) for the adjacent signal terminals (S). It is noted that the ground plane of the wiring layer 13 of the first chip 10 may be connected to the ground plane of the wiring layer 23 of the second chip 20 by the bumps 32 (FIG. 1C).

Alternatively, in the first chip 10, the ground terminal (G) of the terminals 12 may be connected to the ground plane of the second chip 20 via the wirings 14 and the bumps 31 (FIG. 1A).

IO ports IO-1 to IO-8 and pump ports B-1 to B-8 of JPO1 to JPO8 in the region 21 of the second chip 20 are connected to pads IO-1 to IO-8 and B-1 to B-8 of the wiring layer of the first chip 10 by bumps (not shown), respectively. In FIG. 3B, for the sake of simplicity, the pads (pads of the wiring layer of first chip 10) connected to the IO port and the pump port of the JPO of the second chip 20 are designated by the same reference numerals (signs) as the IO port and the pump port of the JPO of the second chip 20.

The pads I0-1 to IO-8 and B-1 to B-8 on the wiring layer 13 of the first chip 10 are connected to a wiring layer 16 on the second surface (back surface) of the first chip 10 via a through via(s) 17, for example, as illustrated in FIG. 3C. The wiring layer 16 on the second surface (back surface) of the first chip 10 is preferably made of the same superconducting material as the wiring layer 13 of the first surface (front surface) of the first chip 10. In FIG. 3C, positions on a plane of the bumps 32 and the through via(s) 17 that connect to pads IO-1 to IO-8 and B-1 to B-8 on the wiring layer 13 of the first chip 10 are the same. However, the positions on the plane of the bumps 32 and the through via(s) 17 connected to pads IO-1 to IO-8 and B-1 to B-8 on the wiring layer 13 of the first chip 10 may not be the same. The pad(s), which is the connection point of the bump(s) 32 with the wiring layer of the first chip 10, may be extended to the through via(s) 17. The through via(s) 17 is illustrated as a conformal via, but may, as a matter of course, be a filled via. The conformal via is a via with a conductive material formed with a constant thickness along a shape of a via hole and the filled via is a via with a via hole filled with a conductive material. A conductive material of the via hole may of course be a superconducting material. In the wiring layer 16 of the first chip 10, wiring(s) may be routed from the through via(s) 17 to connect to connection terminals (connection terminals for connection to the outside) around the first chip 10.

When the quantum device 1 is operated as an actual equipment after testing, connection pads (connection terminals) on the wiring layer 16 (FIG. 3C) of the second surface (back surface) of the first chip 10 and/or pads on the second surface side of the through via(s) 17 may be connected to a wiring layer of a PCB (not shown) by bumps (metal protrusions). Alternatively, they may be connected to a wiring layer of the first surface of another interposer (not shown) by bumps, and further connected to the PCB (not shown) through a socket with a housing accommodating a movable pin with one end thereof in contact with a wiring layer of a second surface of the interposer. Thus, the pads may be connected to a signal source, a read out circuit or the like (both are not shown) disposed outside of a dilution refrigerator, through a connector (e.g., coaxial connector) disposed on the PCB.

Alternatively, as illustrated in FIG. 3D, IO ports IO-1 to IO-8 and pump ports B-1 to B-8 of the JPO 1 to JPO 8 in the region 21 on the first surface of the second chip 20 are connected to a wiring layer 26 of the second surface of the second chip 20 via a through via(s) 27 provided in the substrate 25 of the second chip 20. The through via(s) 27 is illustrated as a conformal via, but it may, of course, be a filled via (via with a conductive material filled insides a via hole). A conductive material of the via hole may, as a matter of course, be a superconducting material.

When the quantum device 1 is used as an actual equipment after testing, connection pads (connection terminals) on the wiring layer 26 of the second surface (back surface) of the second chip 20 and/or pads on the second surface side of the through via(s) 27 may be connected to a wiring layer of a PCB (not shown) by bumps (metal protrusions). Alternatively, the quantum device 1 may be flip-chip mounted on a wiring layer of the first surface of another interposer (not shown) and connected to the PCB (not shown) through a socket with a housing for accommodating a movable pin having one end in contact with a wiring layer of a second surface of the interposer. Thus, the pads may be connected to a signal source, or a read out circuit (both are not shown) disposed outside of a dilution refrigerator, through a connector (e.g., a coaxial connector) disposed on the PCB.

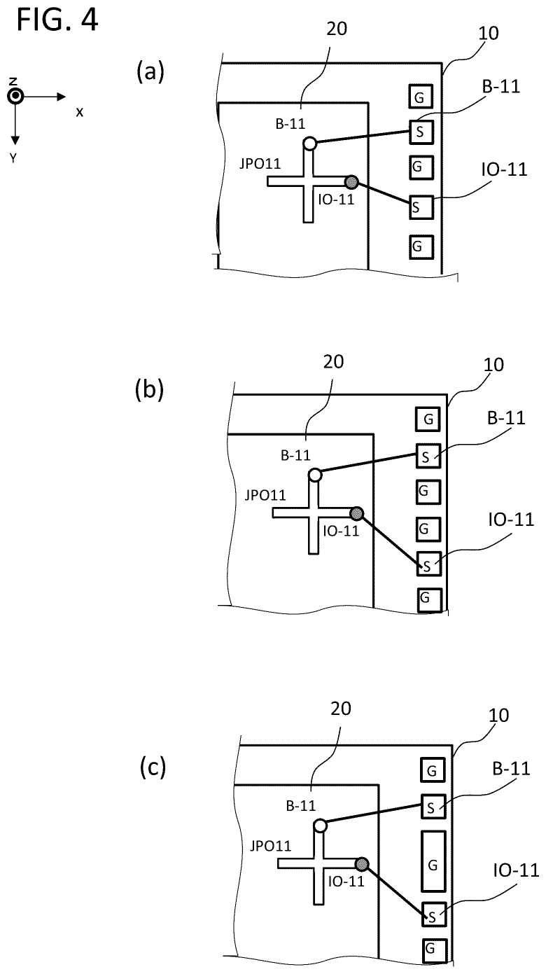

In the first chip 10, regarding an arrangement of a signal terminal (S) which serves as the terminal 12 connected to the circuit under test 22 disposed at the corner of the second chip 20, the ground terminal (G) with a width twice or more of the width of the signal terminal (S) may be disposed on both sides of the signal terminals (S), as illustrated in FIG. 3B. In addition to this configuration, such a configuration may be employed in which an individual ground terminal (G) and an individual signal terminal (S) are disposed alternately (ground terminals (G) are disposed on both sides of each signal terminal (S)), such as G, S, G, S, G, as illustrated inf FIG. 4(a). There may be another configuration in which one ground terminal (G), one signal terminal (S) and one ground terminal (G) configure a unit pattern and unit patterns are repeated plural times, such as [G, S, G], [G, S, G], as illustrated in FIG. 4(b). There may be a further configuration in which one signal terminal (S) is disposed between one ground terminal (G) and a ground terminal having a width twice or more of the width of the signal terminal (S), as illustrated in FIG. 4(c). Since the signal terminal (S) becomes an unused terminal after a probe test, the signal terminal (S) may be connected to the ground terminals (G) provided on both sides thereof.

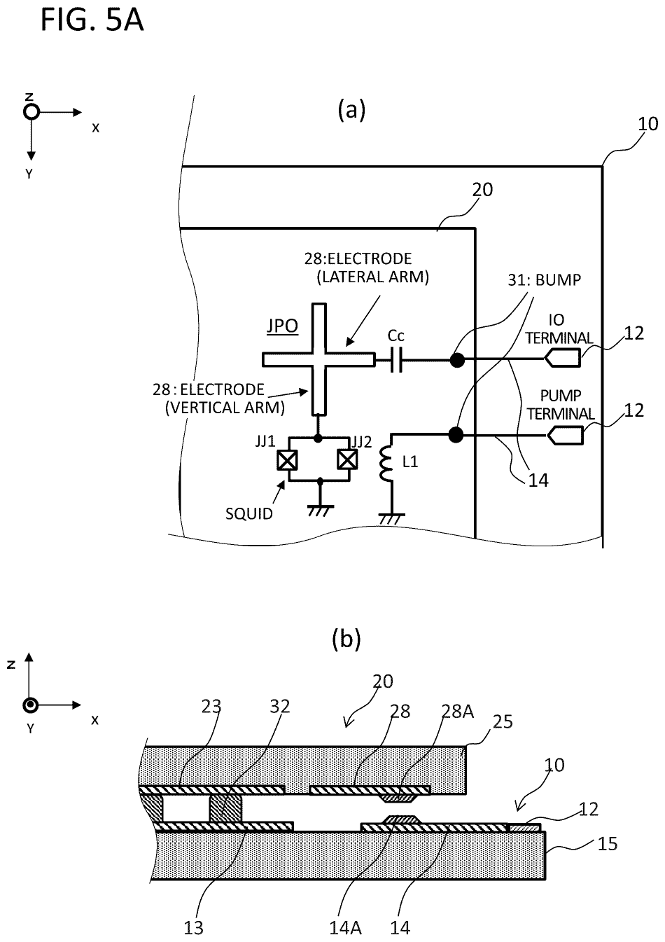

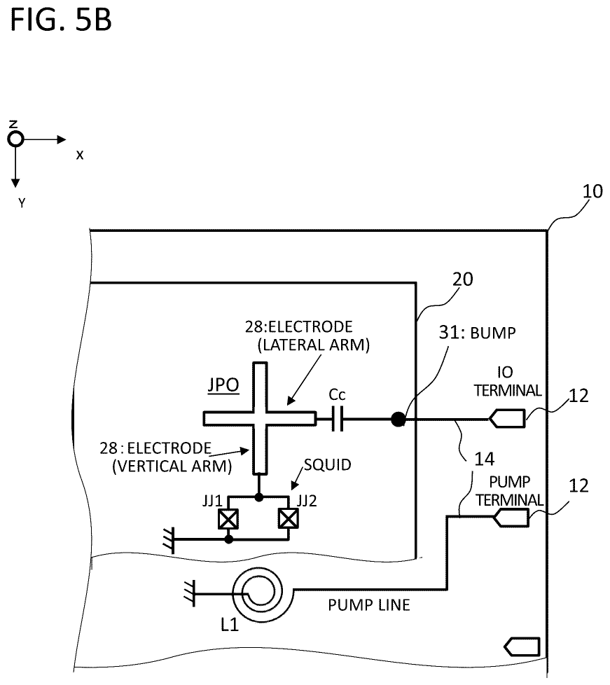

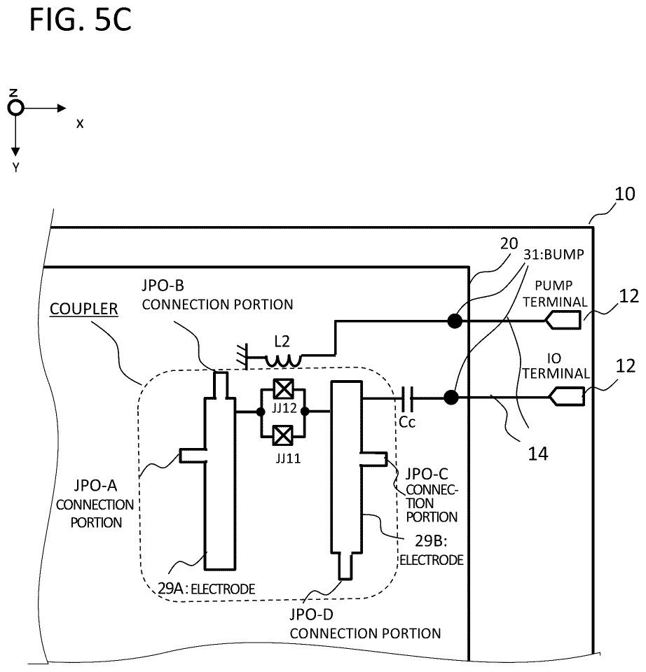

FIG. 5A(a) is a diagram schematically illustrating one example of the JPO in FIG. 3A. FIG. 5A(a) illustrates a connection example as a non-limiting example of the circuit under test 22 of the second chip 20. A SQUID (including Josephson junctions JJ1 and JJ2 in a loop) which is connected between one end of a vertical arm of the cross shaped electrode 28 of the JPO and ground. In testing of the quantum device, an IO terminal (corresponding to the terminal 12 (S) in FIG. 1) of the first quantum chip 10 receives through a probe (not shown) a signal supplied from a test equipment (signal source) arranged outside a dilution refrigerator (not shown). The signal received at the I0 terminal 12 is transmitted via the bump 31 and via capacitive coupling of capacitance Cc to the electrode 28 (lateral (horizontal) arm) of the JPO, which is the circuit under test 22 of the second chip 20. The signal from the JPO (reflection signal) is transmitted from the electrode 28 (lateral arm) of the JPO via capacitive coupling of capacitance Cc and via the bump 31 to the I0 terminal 12 for supply to the test equipment (receiver circuit) arranged outside the dilution refrigerator (not shown). A microwave signal from the test device (signal source) outside the dilution refrigerator (not shown) is supplied to a pump terminal (corresponding to the terminal 12 in FIG. 1) of the first quantum chip 10. In FIG. 5A (a), the ground terminal (G) is omitted which is disposed between the IO terminal and the pump terminal which are the signal terminal (S) in FIG. 4. A signal (current) from the pump terminal is fed to a pump line (inductor L1), which generates a magnetic flux (magnetic field) penetrating through the SQUID loop. The pump terminal may be configured to be supplied with the microwave signal with a DC bias current superimposed by a bias T circuit (not shown). In this case, a pump signal (microwave signal) of approximately twice an angular frequency of a resonance angular frequency ω₀(=2πƒ₀) of the JPO is supplied to the pump terminal. The JPO is caused to oscillate when an intensity of the pump signal exceeds a threshold value, and outputs angular frequency ω₀ signal even when no input signal is present (parametric oscillation). In FIG. 5A(a), the SQUID includes two Josephson junctions JJ1 and JJ2 in the loop, however, the SQUID may as a matter of course, be configured to include three or more Josephson junctions.

Instead of connecting the electrode 28 of the JPO of the second chip 20 and the wiring(s) 14 of the first chip 10 via the bump(s) 31, a protruding portion 28A may be provided on the lateral arm of the electrode 28, as illustrated in FIG. 5A (b) (schematical cross sectional view). The protruding portion 28A of the electrode 28 may be arranged to be faced to a protruding portion 14A provided at one end of the wiring 14 of the first chip 10 such that a capacitive coupling between the electrode 28 and the wiring 14 by capacitance Cc which illustrated in FIG. 5A (a) may be realized.

FIG. 5B is a diagram schematically illustrating a variation example of the circuit under test 22 of the second chip 20 illustrated in FIG. 5A. Referring to FIG. 5B, an inductor L1 is disposed on the wiring layer 13 of the first chip 10, at a position opposing to the SQUID loop of the JPO which is a circuit under test 22 of the second chip 20. The inductor L1 with one end connected to ground is configured to generate a magnetic flux (magnetic field) penetrating through the SQUID loop which includes Josephson junctions JJ1 and JJ2. In the first quantum chip 10, the pump terminal (corresponding to the terminal 12 in FIG. 1) is connected via a pump line (wiring 14) to the other end of the inductor L1. The inductor L1 is, for example, disposed directly under the SQUID loop of the JPO which is the circuit under test 22 of the second chip 20 (in this case, the other end of the inductor L1 may be connected via a straight pump line to a pump terminal). It is noted that in FIG. 5B, the SQUID of the JPO which is the circuit under test 22 of the second chip 20, and the inductor L1 of the first chip 10 are separated from each other on a x-y plane, for the sake of clarity of the drawing. In FIG. 5B, the inductor L1 is illustrated as a spiral inductor. It is preferable for the inductor L1 to have a loop shape configuration as a configuration for generating a magnetic flux (magnetic field) penetrating through the SQUID loop from directly beneath the SQUID loop of the JPO which is the circuit under test 22 of the second chip 20. However, the inductor L1 is not limited to a loop shape. As illustrated in FIG. 5B, such a configuration may be adopted in which at least a part of a qubit circuit which is the circuit under test 22, is provided on the wiring layer 13 of the first quantum chip 10. In FIG. 5B, the ground terminal (G) disposed between the IO terminal and the pump terminal (the signal terminals (S) in FIG. 4) is omitted.

FIG. 5C is a diagram schematically illustrating, as a non-limiting example of the circuit under test 22 of the second chip 20, a coupler that couples four qubits by a four-body interaction. The coupler includes Josephson junctions JJ11 and JJ12, which are connected in parallel between first and second electrodes 29A and 29B (made of superconducting material), facing each other. Two Josephson junctions JJ1 and JJ12 and the first and second electrodes 29A and 29B form a loop (SQUID loop). The first and second electrodes 29A and 29B have connection portions (ports) that are capacitively coupled to two qubits, respectively. A control signal from an IO terminal to initialize the coupler may be transmitted to the coupler through capacitive coupling, and a DC bias current or a microwave signal may be supplied to a pump terminal. In FIG. 5C, a ground terminal (G) disposed between the I0 terminal and the pump terminal (the signal terminals (S) in FIG. 4)) is omitted, as in FIG. 5A and FIG. 5B.

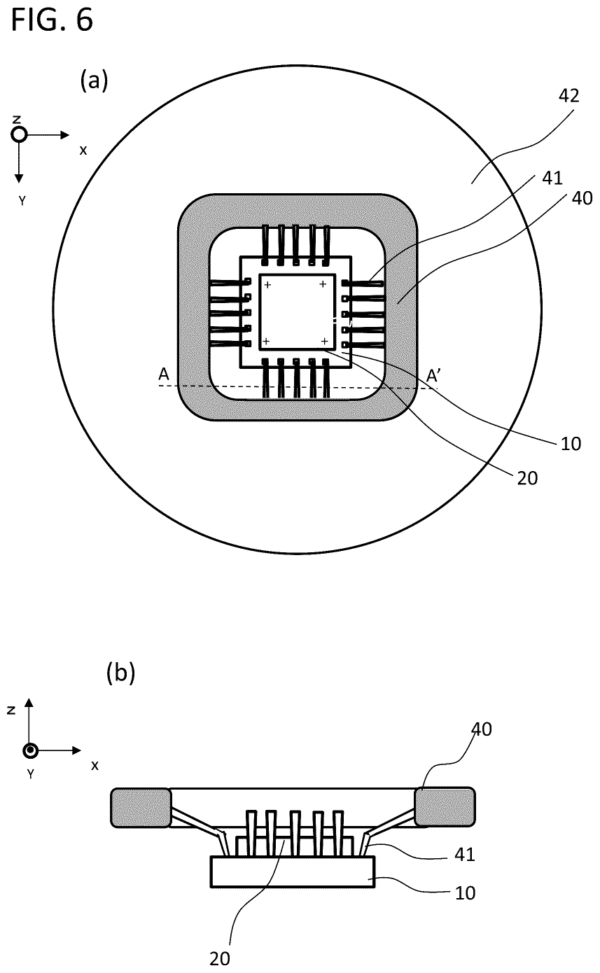

FIG. 6 illustrates an example of a probe test setup of the quantum device 1 with the first chip 10 and the second chip 20 assembled. In FIG. 6, (a) illustrates a schematic plan view of a probe card and (b) illustrates a schematic cross-sectional diagram of the probe card along a line A-A′, viewed from a positive y axis, in (a) of FIG. 6. There is a case where in testing the quantum device 1 by probing the terminals 12 arranged at an outer periphery of the first chip 10 (region protruded from the second chip 20 corresponding to the protruding region 18 in FIG. 1), a cantilever probe card, as illustrated in FIG. 6 is used. In FIG. 6, the probe card 42 is electrically connected to a test equipment (not shown). A tips of a probe pin (needle) 41 protruding at an angle from a support portion 40 is contacted with a surface of each of terminals 12 (signal terminals (S)) arranged along the four sides of the outer periphery portion of the first chip 10 to transmit/receive a signal for testing to/from the terminal 12. The probe pin 41 may include, for example, a palladium alloy, a beryllium copper alloy, or tungsten alloy (such as tungsten rhenium). In a case where the quantum device 1 is placed in a dilution refrigerator and tested under superconducting conditions, the probe pin 41 may be made of a superconducting material. Through holes (not shown) are provided in the probe card 42 (PCB) corresponding to the multiple probe pins 41, and via these through holes, the multiple probe pins 41 are connected to a wiring pattern (not shown) disposed on the PCB. The probe pins 41 (the probe pins 41 contacted with the signal terminals (S)) may be connected to a high-frequency connector (not shown) by wiring (microstrip line) via the through holes for a signal line(s). The probe pins 41 may be connected to the test equipment via a coaxial cable (not shown) from the high-frequency connector (not shown). The probe pins 41, which are contacted with the ground terminals (G), may be configured to be connected to ground (ground plane) of the probe card 42. When performing a continuity test (open/short test) of the circuit under test 22, for example, the quantum device 1 may be tested at room temperature. FIG. 6 illustrates an example of the probe test, and the probe test of the quantum device 1 is, as a matter of course, not limited to the configuration illustrated in FIG. 6. For example, a vertical probe (vertical probe needle) may be used instead of the cantilever-type probe. The probe card 42 may have as a planer form, rectangular instead of circular. FIG. 6 schematically illustrates a configuration where a single quantum device 1 is mounted on the probe card 42, but the probe card 42 may, as a matter of course, be configured to be able to mount multiple quantum devices 1 thereon to conduct parallel testing of the multiple quantum devices 1.

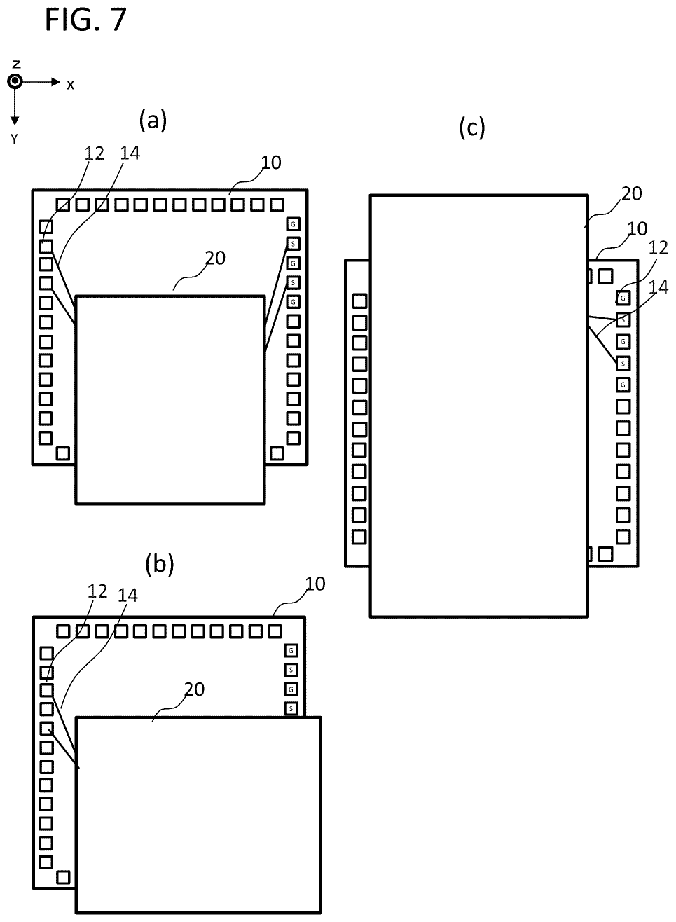

In the above example of the present disclosure, a planar shape of the first chip 10 is larger than that of the second chip 20. When the first chip 10 and the second chip 20 facing to each other are assembled, as illustrated in FIG. 1B, the four sides of the peripheral portion of the first chip 10 protrude from the four sides of the second chip 20. However, the present disclosure is not limited to such a configuration. For example, the second chip 20 may cover one side of the outer periphery portion of the first chip 10, as illustrated in FIG. 7(a), or the second chip 20 may cover two sides of the outer periphery portion of the first chip 10, as illustrated in FIG. 7(b). Alternatively, a planar shape of the second chip 20 may be larger than that of the first chip 10, as illustrated in FIG. 7(c). In this case, a terminal(s) for external connection may be arranged on a second surface (e.g., on the wiring layer 26 illustrated in FIG. 3D) of the second chip 20 opposite to the first surface thereof. In the configurations illustrated in FIGS. 7(a) to (c), the probe pins (FIG. 6) of the probe card may be not provided for the terminals on the four sides of the first chip 10 and the probe pins (FIG. 6) may be configured to probe only necessary terminals 12 (e.g., signal terminals 12 not covered by the second chip 20.

As illustrated in the above examples of the present disclosure, in a quantum device provided with multiple chips (e.g., a first chip and a second chip) in which a superconducting qubit circuit is implemented in a three-dimensional wiring structure, the present disclosure
enables to ensure stable connection performance in testing of a quantum device with the first chip and the second chip assembled;
allows to secure a terminal region for external connection;
ensures a flatness (connection stability) of a terminal(s) (pad(s)) for external connection (because the connection terminal(s) (pad(s)) for external connection are not subject to probe testing, and no probe pin contact damage occurs on the terminals (pads) for external connection.
facilitates a probe test to detect failure (such as operation failure and/or performance degradation or fault of a superconducting qubit circuit) caused by misalignment, etc. in connection of the first chip and the second chip (enhancing Design for Testability). This is because the quantum device of a stacked structure includes terminals (pads) to be contacted by the probe pin in a region (protruding region) protruding outward from a side edge of the second chip in an outer periphery portion of the first chip and there is no obstruction above the terminals (pads);
further facilitates to detect operation failure and/or performance degradation or fault of the superconducting qubit circuit caused by misalignment, etc. in connection of the first chip and the second chip, by disposing a circuit under test (to be subjected to a probe test) at the corner(s) of the first chip.

The above examples disclose a configuration in which the quantum circuit is arranged within the region 21 on the first surface of the second chip 20 flip-chip mounted on the first surface of the first chip 10 to implement the quantum circuit of a three-dimensional wiring structure. However, the present disclosure is as a matter of course. not limited to this configuration. The quantum circuit may be arranged on a wiring layer 13 of the first surface of the first chip 10. Alternatively, a first quantum circuit (e.g., a part of the quantum circuit) arranged on a wiring layer 13 of the first surface of the first chip 10 and a second quantum circuit (e.g., a remaining part of the quantum circuit) arranged on a wiring layer 23 of the first surface of the second chip 20 flip-chip mounted on the first surface of the first chip 10 may compose an entirety of the quantum circuit of a three-dimensional wiring structure.

The above examples of the disclosure can partially or entirely be described as following Supplementary notes (Notes), though not limited thereto.
(Note 1) A quantum device, including: a first chip; and a second chip, the first chip and the second chip assembled to configure a superconducting quantum circuit of a three-dimensional wiring structure, wherein the first chip includes: a protruding region protruded from a side edge of an outer periphery of the second chip; and at least one terminal disposed on the protruding region.
(Note 2) The quantum device according to Note 1, wherein the first chip and the second chip are arranged with a first surface of the first chip opposed to a first surface of the second chip, and wherein the superconducting quantum circuit is arranged on at least one of the first surface of the first chip and the first surface of the second chip.
(Note 3) The quantum device according to Note 1 or 2, wherein the protruding region of the first chip is an outer edge region of the first chip, protruded from the side edge of the outer periphery of the second chip, and wherein the at least one terminal on the outer edge region is provided for testing of at least one of the first chip and the second chip assembled. A planar chape of the first chip is larger than that of the second chip. Alternatively, the planar chape of the first chip may be smaller or equal to that of the second chip.
(Note 4) The quantum device according to any one of Notes 1 to 3, wherein at least one of the first chip and the second chip includes a circuit under test electrically connected to the at least one terminal disposed on the protruding region of the first chip, the circuit under test being tested using the at least one terminal.
(Note 5) The quantum device according to any one of Notes 1 to 3, wherein the second chip includes a circuit under test on an outer periphery of the second chip, the circuit under test electrically connected to the at least one terminal disposed on the protruding region of the first chip, the circuit under test being tested using the at least one terminal.
(Note 6) The quantum device according to any one of Notes 1 to 3, wherein the second chip includes a circuit under test on at least one corner of four corners of the second chip, the circuit under test electrically connected to the at least one terminal disposed in the protruding region of the first chip, the circuit under test being tested using the at least one terminal.
(Note 7) The quantum device according to Note 4 or 5, wherein the circuit under test includes at least one selected from a group including a qubit, a coupler, a resonator, an oscillator, a Superconducting Quantum Interference Device (SQUID), and a magnetic field application circuit. The coupler may couple two or four qubits.
(Note 8) The quantum device according to any one of Notes 1 to 7, wherein a plurality of terminals includes signal terminals connected to signal lines of the circuit under test and ground terminals assigned to ground, wherein the ground terminals are disposed on both sides of the signal terminals, and the ground terminals disposed between adjacent signal terminals have an area larger than that of the signal terminals, or at least one ground terminal that has a same area as the signal terminal.
(Note 9) The quantum device according to any one of Notes 1 to 8, wherein the first chip includes a terminal for external connection on a surface opposite to a surface facing the second chip.

(Note 10) The quantum device according to any one of Notes 1 to 8, wherein the second chip includes a terminal for external connection on a surface opposite to a surface facing the first chip.
(Note 11) The quantum device according to any one of Notes 1 to 8, wherein the second chip includes a plurality of circuit elements constituting the superconducting quantum circuit within a region on a wiring layer of a first surface of the second chip, the region enclosed by a periphery of the first surface of the second chip.
(Note 12) The quantum device according to Note 6, wherein the circuit under test provided on the at least one corner of four corners of a first surface of the second chip is connected via a bump to a wiring layer on a first surface of the first chip, opposing to the first surface of the second chip, and further connected by a wiring to the at least one terminal disposed on the protruding region that is an outer edge of the first surface of the first chip.
(Note 13) The quantum device according to Note 6, wherein the circuit under test provided on at least one corner of four corners of a first surface of the second chip includes a first terminal connected by capacitive or inductive coupling to a second terminal facing to the first terminal and disposed on a first surface of the first chip, opposite to the first surface of the second chip, the second terminal connected by a wiring to the at least one terminal disposed on the protruding region that is an outer edge of the first surface of the first chip.
(Note 14) The quantum device according to Note 11, wherein the plurality of circuit elements of the superconducting quantum circuit arranged on the first surface of the second chip are connected to a wiring layer on a first surface of the first chip, opposing to the first surface of the second chip via bumps,
   the first surface of the first chip being connected to a wiring layer of a second surface of the first chip opposite to the first surface thereof via through vias, the wiring layer on the second surface of the first chip including a plurality of terminals for external connection.
(Note 15) The quantum device according to Note 11, wherein the first surface of the second chip is connected to a second surface of the second chip opposite to the first surface thereof via through vias,
   the plurality of circuit elements of the superconducting quantum circuit arranged on the first surface of the second chip are connected to a wiring layer on the second surface of the second chip via the though vias, the wiring layer on the second surface of the second chip including a plurality of terminals for external connection.
(Note 16) The quantum device according to Note 11, wherein a wiring layer on the first surface of the first chip includes at least a ground plane provided on each longitudinal side of the signal line via a gap, the ground plane extended to a location where the ground terminal is to be disposed to serve as the ground terminal.
(Note 17) The quantum device according to Note 1 or 2, wherein the circuit under test includes a plurality of circuit elements,
   the first chip including a part of the plurality of circuit elements of the circuit under test on a first surface thereof, the part of the plurality of circuit elements electrically connected to the at least one terminal disposed on the protruding region that is an outer edge of the first surface of the first chip,
   the second chip including remaining circuit elements of the circuit under test on a first surface thereof facing to the first surface of the first chip, the remaining circuit elements of the circuit under test electrically connected to at least a second terminal disposed on the protruding region that is an outer edge of the first surface of the first chip.

The disclosure of each of PTL 1 to 4 is incorporated herein by reference thereto. Variations, adjustments, and combination of the examples of the present disclosure are possible within the scope of the overall disclosure (including the claims) and based on the basic technical concept of the present disclosure. Various combinations and selections of various disclosed elements (including the elements in each of the claims, examples, drawings, etc.) are possible within the scope of the claims of the present disclosure. That is, the present disclosure includes various variations and modifications that could be made by those skilled in the art according to the overall disclosure including the claims and the technical concept.

What is claimed is:

1. A quantum device comprising:
a first chip; and
a second chip, the first chip and the second chip assembled to configure a superconducting quantum circuit of a three-dimensional wiring structure, wherein the first chip includes:
a protruding region protruded from a side edge of an outer periphery of the second chip; and
at least one terminal disposed on the protruding region.

2. The quantum device according to claim 1, wherein the first chip and the second chip are arranged with a first surface of the first chip opposed to a first surface of the second chip, and
wherein the superconducting quantum circuit is arranged on at least one of the first surface of the first chip and the first surface of the second chip.

3. The quantum device according to claim 1, wherein the protruding region of the first chip is an outer edge region of the first chip, protruded from the side edge of the outer periphery of the second chip, and
wherein the at least one terminal on the outer edge region is provided for testing of at least one of the first chip and the second chip assembled.

4. The quantum device according to claim 1, wherein at least one of the first chip and the second chip includes a circuit under test electrically connected to the at least one terminal disposed on the protruding region of the first chip, the circuit under test being tested using the at least one terminal.

5. The quantum device according to claim 1, wherein the second chip includes a circuit under test on an outer periphery of the second chip, the circuit under test electrically connected to the at least one terminal disposed on the protruding region of the first chip, the circuit under test being tested using the at least one terminal.

6. The quantum device according to claim 1, wherein the second chip includes a circuit under test on at least one corner of four corners of the second chip, the circuit under test electrically connected to the at least one terminal disposed in the protruding region of the first chip, the circuit under test being tested using the at least one terminal.

7. The quantum device according to claim 4, wherein the circuit under test includes at least one selected from a group including a qubit, a qubit coupler, a resonator, an oscillator, a Superconducting Quantum Interference Device (SQUID), and a magnetic field application circuit.

8. The quantum device according to claim 4, wherein the terminals disposed in the protruding region of the first chip includes at least one signal terminal electrically connected to at least one signal line of the circuit under test and at least one ground terminal connected to ground,
on both sides of the signal terminal provided the ground terminals disposed,
wherein the ground terminal provided between adjacent signal terminals has an area larger than an area of the signal terminal, or at least one ground terminal provided between the adjacent signal terminals, has an area same as an area of the signal terminal.

9. The quantum device according to claim 1, wherein the first chip includes a terminal for external connection on a second surface opposite to a first surface facing the second chip.

10. The quantum device according to claim 1, wherein the second chip includes a terminal for external connection on a second surface opposite to a first surface facing the first chip.

11. The quantum device according to claim 1, wherein the second chip includes a plurality of circuit elements constituting the superconducting quantum circuit within a region on a wiring layer of a first surface of the second chip, the region enclosed by a periphery of the first surface of the second chip.

12. The quantum device according to claim 6, wherein the circuit under test provided on the at least one corner of four corners of a first surface of the second chip is connected via a bump to a wiring layer on a first surface of the first chip, opposing to the first surface of the second chip, and further connected by a wiring to the at least one terminal disposed on the protruding region that is an outer edge of the first surface of the first chip.

13. The quantum device according to claim 6, wherein the circuit under test provided on at least one corner of four corners of a first surface of the second chip includes a first terminal connected by capacitive or inductive coupling to a second terminal facing to the first terminal and disposed on a first surface of the first chip, opposite to the first surface of the second chip, the second terminal connected by a wiring to the at least one terminal disposed on the protruding region that is an outer edge of the first surface of the first chip.

14. The quantum device according to claim 11, wherein the plurality of circuit elements of the superconducting quantum circuit arranged on the first surface of the second chip are connected to a wiring layer on a first surface of the first chip, opposing to the first surface of the second chip via bumps,
the first surface of the first chip being connected to a wiring layer of a second surface of the first chip opposite to the first surface thereof via through vias, the wiring layer on the second surface of the first chip including a plurality of terminals for external connection.

15. The quantum device according to claim 11, wherein the first surface of the second chip is connected to a second surface of the second chip opposite to the first surface thereof via through vias,
the plurality of circuit elements of the superconducting quantum circuit arranged on the first surface of the second chip are connected to a wiring layer on the second surface of the second chip via the though vias, the wiring layer on the second surface of the second chip including a plurality of terminals for external connection.

16. The quantum device according to claim 11, wherein a wiring layer on the first surface of the first chip includes at least a ground plane provided on each longitudinal side of the signal line via a gap,
the ground plane extended to a location where the ground terminal is to be disposed to serve as the ground terminal.

17. The quantum device according to claim 1, wherein the circuit under test includes a plurality of circuit elements,
the first chip including a part of the plurality of circuit elements of the circuit under test on a first surface thereof, the part of the plurality of circuit elements electrically connected to at least a first terminal disposed on the protruding region that is an outer edge of the first surface of the first chip,
the second chip including remaining circuit elements of the circuit under test on a first surface thereof facing to the first surface of the first chip, the remaining circuit elements of the circuit under test electrically connected to at least a second terminal disposed on the protruding region that is an outer edge of the first surface of the first chip.
